(19) United States
(12) Patent Application Publication
(10) Pub. No.: US 2005/0202352 A1
(43) Pub. Date: Sep. 15, 2005

(54) Systems and methods for sub-wavelength imaging

(75) Inventors: David Cyganski, Holden, MA (US); W. Grant McGimpsey, Boylston, MA (US)

Correspondence Address: LAHIVE & COCKFIELD, LLP., 28 STATE STREET, BOSTON, MA, 02109, US

(73) Assignee: Worcester Polytechnic Institute, Worcester, MA (US)

(21) Appl. No.: 10/798,822

(22) Filed: Mar. 11, 2004

(51) Int. Cl. G03F 7/20

(52) U.S. Cl. 430/394; 430/322

(57) ABSTRACT

Preferred embodiments of the present invention provide methods of forming a photolithographic pattern by patternwise imaging each of two or more different modalities of light onto a multiphoton-specific photoinitiator material to form a photolithographic pattern on the surface where each of the patterns of the two or more different wavelengths of light overlap. In various embodiments, the invention provides a method of semiconductor fabrication capable of permitting the formation of an imaged feature having a dimension smaller than λ/(2 NA), where λ is the smallest wavelength of imaging light, and NA is the numerical aperture of the imaging system.

### BACKGROUND OF THE INVENTION

Photographic lithography, often referred to simply as photolithography, is the primary tool today for manufacture of integrated circuits, Micro-Electro-Mechanical Systems (MEMS) and photonic structures. The continuing increase in computer processing speeds and decrease in the size, cost and power consumption of electronics is directly attributable to progress in the formation of features of decreasing size through improvements in lithography. Semiconductor industry leaders have followed an improvement path since 1975 and codified a technology roadmap since 1992, extending to 2016, which calls for a halving of feature area size every two years (halving feature width every four years). However, the semiconductor industry, a $60 billion industry in the U.S. alone, is facing increasing difficulty in achieving the required lithographic resolution requirements.

A fundamental principle of classic Fourier imaging, i.e., the diffraction limit or fundamental resolution limit, dictates a minimum imaged feature width proportional to λ/(2 NA) where λ is the wavelength of the light being imaged and NA is the numerical aperture of the imaging system (which is primarily a function of the size of the lens which has a maximum value of 1). This resolution limit is determined by the minimum distance between two minima of the image formed. Traditionally, the backbone of lithographic performance improvement has been reductions in the wavelength of light in the imaging process and increases in the numerical aperture. The sequence of improvements has driven the wavelength from the visible region into the extreme ultraviolet while the numerical aperture is already near its ultimate value of 1. For example, today's lithographic tools are based upon the 193 nanometer output of an argon fluoride excimer laser and a numerical aperture of 0.75.

However, the industry roadmap becomes more difficult to follow with decreasing wavelengths owing to the paucity of materials that are transparent and optically well behaved at smaller wavelengths. For example, the industry plan was to use 157 nm fluorine lasers in 2007, but such plans have been put on hold or abandoned by various manufacturers in the industry because, it is believed, the targeted 157 nm lens material, calcium fluoride (CaF₂), has been found to be intrinsically optically birefringent to an unacceptable degree. There still remains a need to decrease the size of features for a given wavelength and lens technology.

### SUMMARY OF THE INVENTION

In preferred embodiments, the present invention provides methods that facilitate the formation of features of less than the size allowed by the classic diffraction limit for a given wavelength and numerical aperture using a single wavelength of light.

In various aspects, the present invention provides methods for forming a photolithographic pattern. The preferred embodiments of the present invention involve the separation of two imaging processes by exploitation of two different modalities of light such as, for example, two wavelengths of light, two polarizations of light, two optical angular momentum states of light, and two pulse widths. Any process that forms an exposure from the product of two such images can then be used to obtain features with a fundamental resolution limit that is half the size accessible with the lower of the two wavelengths of light involved in the image formation process.

In preferred embodiments, this method may be applied to existing photolithography processes. Furthermore, various embodiments of the invention provide a photolithographic approach that can be exploited to further decrease the feature size by larger integer factors such as, for example, without limitation, 3 and 4, . . . , for any given optical wavelength and numerical aperture.

In accordance with a preferred embodiment, a method of forming a photolithographic pattern includes the steps of providing a surface having a multi-photon-specific photoinitiator material disposed thereon; irradiating in a first irradiation pattern at least a portion of the multi-photon-specific photoinitiator material with a first wavelength of light capable of electronically exciting the irradiated portion of the multi-photon-specific photoinitiator to a first excited electronic state; irradiating in a second irradiation pattern at least a portion of the multi-photon-specific photoinitiator material with a second wavelength of light, the second wavelength of light being capable of electronically exciting the portion of the multi-photon-specific photoinitiator irradiated by both the first wavelength of light and the second wavelength of light to a second excited electronic state, the multi-photon-specific photoinitiator material in the second excited electronic state being capable of undergoing a chemical reaction to form a photolithographic pattern on the surface. The surface includes one or more layers of material on a semiconductor substrate. The multi-photon-specific photoinitiator material includes, without limitation, benzil or phenothiazine.

The first wavelength of light includes light having a wavelength in the range between about 100 nanometers (nm) and about 1100 nm and the second wavelength of light includes light having a wavelength in the range between about 100 nm and about 1100 nm. In a preferred embodiment, the first wavelength of light has a wavelength preferably in the range between about 100 nm and about 450 nm and the second wavelength of light has a wavelength in the range between about 450 nm and about 700 nm.

In a preferred embodiment, the first excited electronic state includes a singlet state, and the second excited electronic state includes a triplet state. The step of irradiating in a first irradiation pattern further includes imaging the first wavelength of light onto the multi-photon-specific photoinitiator material through a first photolithographic mask; and the step of irradiating in a second irradiation pattern further comprises imaging the second wavelength of light onto the multi-photon-specific photoinitiator material through a second photolithographic mask different from the first photolithographic mask. In preferred embodiments, additional photolithographic masks can be used with one or more of the first wavelength of light and the second wavelength of light to form a final photolithographic image.

In the preferred embodiments, the chemical reaction includes one of acid generation, free radical generation, polymerization and/or generating a material resistant to acid when contacted with a developing solution or other conditions. The photolithographic pattern on the surface comprises an etching mask for the surface.

The photolithographic pattern includes at least one feature having a dimension smaller than λ/(2 NA) which cannot have been formed at the same resist exposure contrast level with a typical single-wavelength diffraction limited optical system, where λ is the first wavelength of light or the second wavelength of light, and NA is the numerical aperture of an imaging system used to irradiate the multi-photon-specific photoinitiator with the light of wavelength of λ.

The method in accordance with a preferred embodiment, further includes the step of irradiating in a third irradiation pattern at least a portion of the multi-photon-specific photoinitiator material with a third wavelength of light, different from the first wavelength of light and the second wavelength of light, the third wavelength of light capable of electronically exciting the portion of the multi-photon-specific photoinitiator to irradiated by both the first wavelength of light and the third wavelength of light to a third excited electronic state having an energy greater than the first excited electronic state but less than the second excited electronic state, wherein the second wavelength of light is capable of electronically exciting the portion of the multi-photon-specific photoinitiator irradiated by the first wavelength of light, the third wavelength of light and the second wavelength of light to a second excited electronic state.

The foregoing and other aspects, embodiments and features of the system and method for sub-wavelength imaging will be apparent from the following more particular description of preferred embodiments of the system and method as illustrated in the accompanying drawings in which like reference characters refer to the same parts throughout the different views. The drawings are not necessarily to scale, emphasis instead being placed upon illustrating the principles of the invention.

### BRIEF DESCRIPTION OF THE DRAWINGS

FIG. 1 illustrates a product exposure pattern formed with half the feature size provided by either of the constituent image patterns in accordance with preferred embodiments of the present invention.

FIG. 2 is a flow diagram illustrating a method for forming a photolithographic pattern in accordance with preferred embodiments of the present invention.

FIG. 3 schematically illustrates an electronic state diagram representation of a multi-photon specific irradiation of a multi-photon-specific photoinitiator material resulting in chemical reaction of a portion thereof in accordance with preferred embodiments of the present invention.

FIG. 4 schematically illustrates a multi-photon specific irradiation of benzil resulting in photoinitiated radical generation of polymerization in accordance with preferred embodiments of the present invention.

FIG. 5 schematically illustrates a multi-photon specific irradiation of phenothiazine resulting in photoinitiated acid generation in accordance with various preferred embodiment of the present invention.

### DETAILED DESCRIPTION OF THE INVENTION

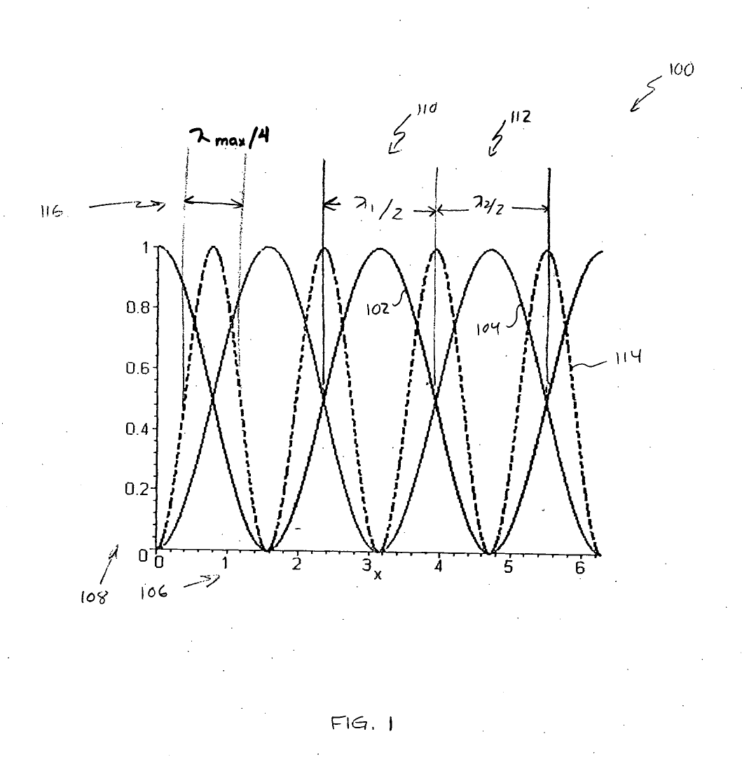

Consider the plot 100 of FIG. 1, in which the two solid curves 102, 104 represent the intensity profiles of two diffraction patterns formed by two wavelengths of light, λ₁ and λ₂, assuming for purposes of the illustration, though not limited to, the numerical aperture (NA) is =1, and wherein the abscissa 106 is in arbitrary units of distance, and the ordinate 108 is in arbitrary units of intensity. To further illustrate, it is assumed that the patterns are both formed with a 100%, though not limited to, contrast line spacing equal to that allowed by diffraction limited imaging with the wavelength λₘₐₓ, and wherein λₘᵢₙ is the shorter wavelength of λ₁ and λ₂. The shorter wavelength of light can produce the pattern with spacing shown since it operates within the diffraction limit. Accordingly, for the first wavelength λ₁ it can be seen that its diffraction pattern 102 has peaks (and troughs) spaced by (λₘₐₓ/2) 110 and for the second wavelength λ₂ it can be seen that its diffraction pattern 104 has peaks (and troughs) spaced by (λₘₐₓ/2) 112. The dotted curve 114 in FIG. 1 denotes an image that can be formed by a material responding to the product of these images, where it can be seen that its pattern 114 has a fundamental spacing limit of (λₘₐₓ/4) 116.

By appropriate choices of imaging masks and geometries in preferred embodiments, the present invention can obtain equal line spacings at intervals greater than λₘₐₓ/4, and obtain other features with similar dimensions. Also, by shifting one of the diffraction patterns it can become possible to place one trough associated with λ₁ closer than λₘₐₓ/4 to a trough associated with λ₂ hence creating substantially 100% contrast features (in illustrative example of the diffraction limited case) of size smaller than λ/4.

Two general types of media, in accordance with preferred embodiments, without limitation, for obtaining this product behavior are, for example, (1) a medium having a chemical species that undergoes a specific change upon excitation with only one photon from each of the two wavelengths; and (2) a medium doped with two chemical species that each undergo change under excitation from one of the two wavelengths, respectively, forming two intermediate species that react either spontaneously or under further excitation or catalysis to form a final chemical product. Such media are examples of what are referred to as a “multi-photon-specific photoinitiator” herein after.

In either embodiment, the desired end result can be the fixation of the product photolithographic pattern as an acid resistant material (resist) through polymerization or similar processes, which then forms the basis for classic lithographic processing through, for example, the selective removal (etching) of materials through exposure to etchants.

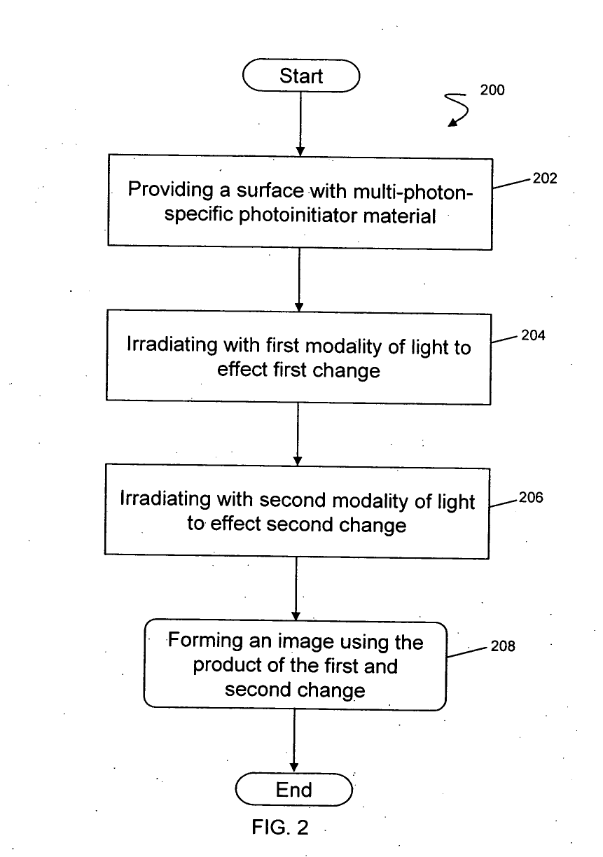

Referring to FIG. 2, various aspects of the present invention provide methods for forming a photolithographic pattern as follows and illustrated in the flow diagram 200. A surface having a multi-photon-specific photoinitiator material is provided in step 202 which is irradiated with a first modality of light to effect a first change per step 204 in the multi-photon-specific photoinitiator material and with a second modality of light (different from the first) to effect a second change in the multi-photon-specific photoinitiator material per step 206. A photolithographic pattern is then formed per step 208 in at least a portion of those regions of the multi-photon-specific photoinitiator material that have undergone both the first and second changes.

In preferred embodiments, the first and second modalities of light include wavelengths. In various embodiments, the multi-photon-specific photoinitiator material is a medium doped with a chemical species that undergoes a specific change upon excitation with only one photon from each of the two wavelengths. In preferred embodiments, the first change includes exciting the irradiated portion of the multi-photon-specific photoinitiator to a first excited electronic state, such as, for example, an excited singlet state, and the second change includes electronically exciting the portion of the multi-photon-specific photoinitiator irradiated by both the first wavelength of light and the second wavelength of light to a second excited electronic state. The multi-photon-specific photoinitiator material in the second excited electronic state is then capable of undergoing a chemical reaction to form, for example, a photolithographic pattern on the surface. Examples of such chemical reactions include, but are not limited to, spontaneous reaction (for example, by polymerization), and reaction after further treatment (for example, by being developed to produce a resist).

In preferred embodiments, the multi-photon-specific photoinitiator material is a medium doped with two chemical species that each undergo change under excitation from one of the two wavelengths, respectively, forming two intermediate species that react either spontaneously or under further excitation or catalysis to form a final chemical product. In preferred embodiments, the first change includes formation of a first intermediate species out of a first chemical species of the multi-photon-specific photoinitiator material and the second change includes formation of a second intermediate species out of a second chemical species of the multi-photon-specific photoinitiator material. The regions of the multi-photon-specific photoinitiator material where both the first intermediate species and second intermediate species are present are then capable of undergoing a chemical reaction to form a photolithographic pattern on the surface. Examples of such chemical reactions include, but are not limited to, reaction with each other (for example, by polymerization), catalysis by one intermediate species of a spontaneous reaction of the other intermediate species, catalysis by one intermediate species of a reaction of the other intermediate species with other chemical species, and reaction after further treatment of one or both of the first and second intermediate species.

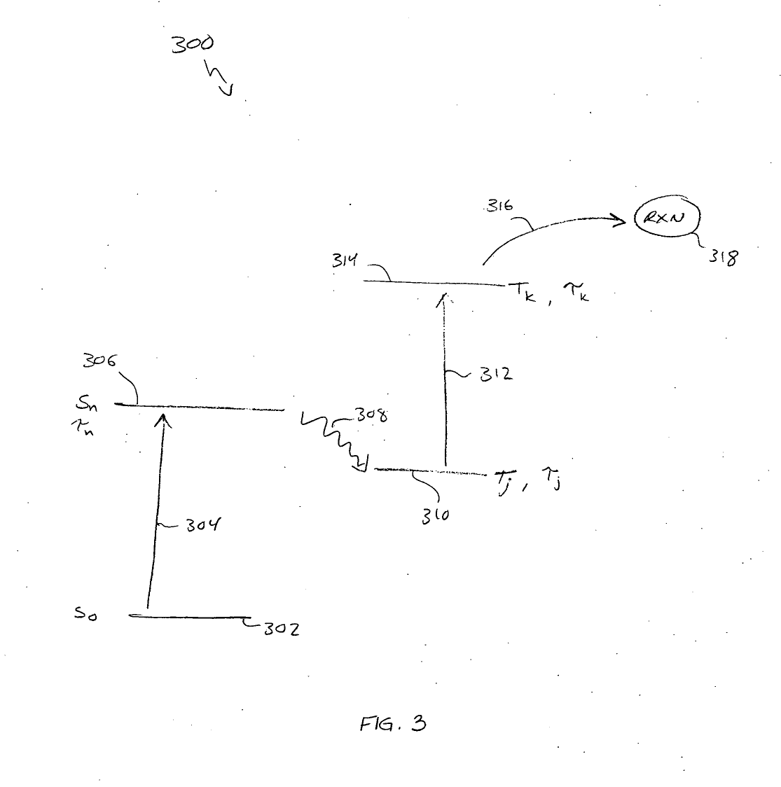

FIG. 3, illustrates the principles behind one set of preferred embodiments of a multi-photon-specific photoinitiator material having a medium with a chemical species that undergoes a specific change upon excitation with only one photon from each of two wavelengths. FIG. 3 illustrates these principles schematically in the form of an electronic state diagram 300 wherein the energy associated with an electronic state increases as the electrons move from the bottom to the top of the diagram. In various preferred embodiments, the first change comprises electronic excitation of a chemical species of the multi-photon-specific photoinitiator material from a ground electronic state 302 by light of a first wavelength 304 to a first excited electronic state 306. Preferably, but not necessarily, light of the first wavelength is provided by a monochromatic light source such as a pulsed or continuous wave (CW) laser. In various preferred embodiments, the ground state and first excited electronic state are singlet states, however, the first excited electronic state need not be the lowest energy excited electronic state of the chemical nor the lowest energy excited state in the manifold of states of like spin multiplicity as the ground state. For example, the first excited electronic state need not be the lowest excited singlet electronic state for a singlet ground state species.

In various preferred embodiments, the first excited electronic state 306 can undergo an intersystem crossing 308 to another state of different spin multiplicity; illustrated as a crossing from a manifold of singlet states to a triplet state Tⱼ 310 in a manifold of triplet states. Preferably the lifetime τₙ of the excited electronic state 306 is greater than about 1 picosecond (ps) to permit efficient population of the triplet state Tⱼ 310, such as, for example, by intersystem crossing. In various preferred embodiments, the second change then comprises electronic excitation of a chemical species of the multi-photon-specific photoinitiator material in the triplet state Tⱼ 310 by light of a second wavelength 312 to a second excited electronic state Tₖ 314. Preferably, but not necessarily, light of the second wavelength is also provided by a monochromatic light source such as a pulsed or CW laser. In various embodiments, the second excited electronic state is a triplet, however, the second excited electronic state need not be the highest energy excited electronic state of the chemical species nor the second lowest energy excited electronic state of the chemical species. Preferably the lifetime τⱼ of the triplet state Tⱼ 310 is greater than about 1 nanosecond (ns), and more preferably greater than about 1 microsecond (μs) to permit efficient population of the second excited electronic state Tₖ 314 by the second wavelength of light 312.

In various preferred embodiments, the second excited electronic state Tₖ 314 correlates to a reaction coordinate 316 that produces a moiety capable of undergoing a chemical reaction 318 to form a photolithographic pattern on the surface. Preferably the lifetime τₖ of the second excited electronic state Tₖ 314 is greater than about 1 ps to permit the chemical reaction 318 to proceed to a desired degree. Suitable second excited electronic state Tₖ 314 lifetimes τₖ can be chosen, for example, based on the extent and efficiency of non-chemical deactivation processes compared to the efficiency of the desired chemical reaction 318. In various embodiments, τₖ is as long as possible.

Examples of chemical reactions suitable for formation of a photolithographic pattern on a surface in accordance with the present invention include, but are not limited to, free radical and photoacid catalyzed polymerization. Free radical and photoacid catalyzed polymerization are processes used to fix optical excitation patterns in resist materials. In preferred embodiments, the invention involves the use of compounds that can undergo radical formation or photoacid formation following the sequential absorption of two or more photons which have either the same or different wavelengths. The photochemical mode of action can be described as follows. The multi-photon-specific photoinitiator material comprises a photoactive compound which is photoexcited by the output of a light source, preferably, but not necessarily limited to, a monochromatic light source such as a pulsed or CW laser emitting radiation with a wavelength that falls within the absorption band of the ground state of the compound. A consequence of this excitation can be the production of an excited singlet state that can decay by a variety of processes, one of which is intersystem crossing to an excited triplet state. However, preferably little or no permanent chemical change occurs as a result of this excitation step, i.e., no radical or acid generation occurs nor is there any efficient intermolecular reaction with quencher species. In the absence of any further excitation, the excited states decay back to the ground state by the emission of energy either in thermal or photonic form. Thus, under the conditions of this one-photon excitation, preferably little or no reactions occur.

During the lifetime of the excited state, which, depending on its multiplicity (singlet or triplet) and its environment, for example, but not limited to, solid state, oxygen present, may be short (nanoseconds) or long (>seconds), a second light source, again preferably, although not necessarily limited to, a monochromatic source such as a laser, with an output wavelength matching one or more of the wavelengths at which the excited state or states absorb, serves to further excite the molecule into an upper excited state, either an upper triplet or an upper singlet state, with energy higher than the lowest excited state. This upper excited state subsequently results in a chemical change in the photoactive compound resulting in the formation of a free radical or an acid, either of which can initiate polymerization in polymers commonly used in photoresist formulations, for example, by radical-initiated polymerization, acid-initiated polymerization, or both. Such molecules, i.e., those that undergo this kind of chemical change only under two-photon conditions are referred to herein as “multi-photon-specific photoinitiators.”

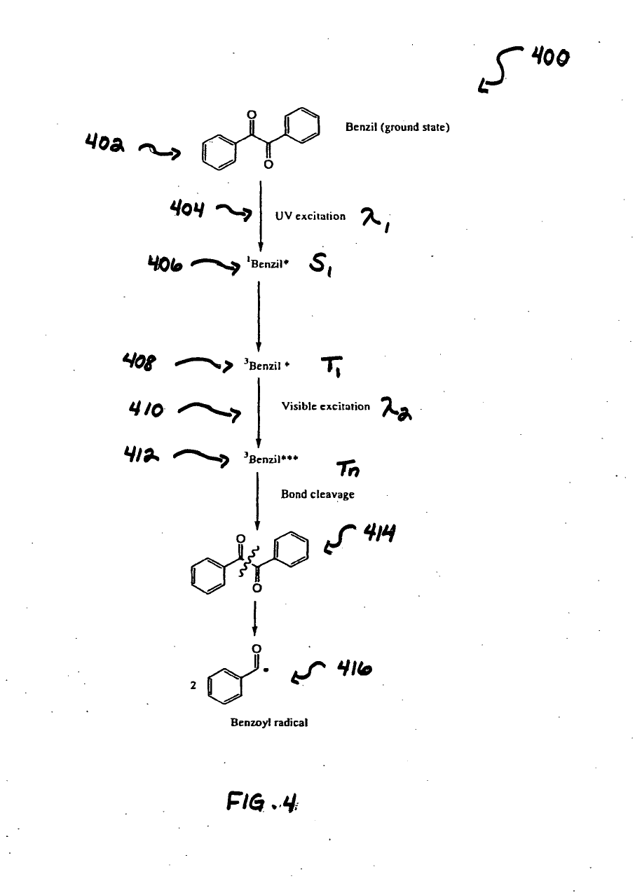

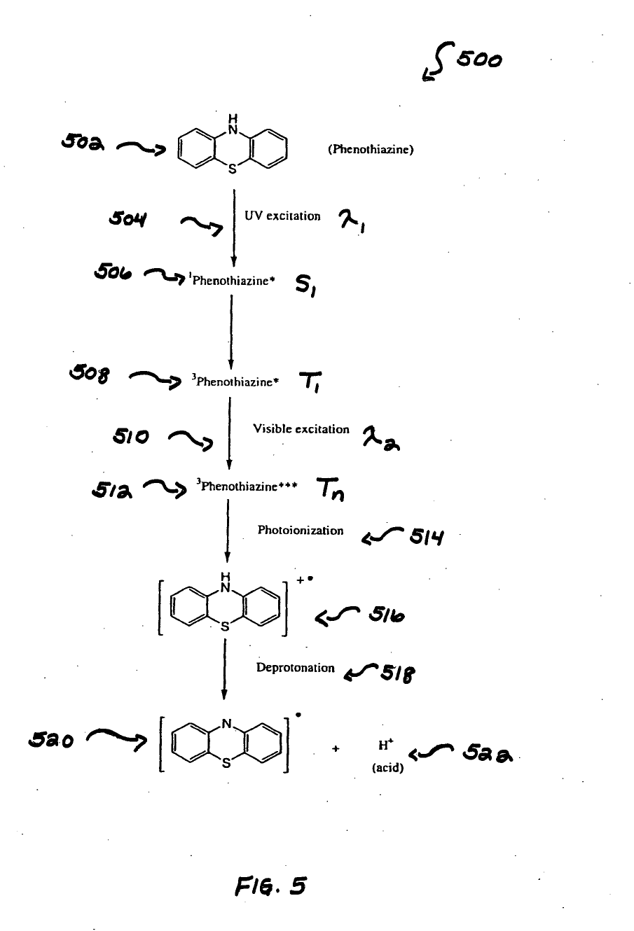

Specific examples of multi-photon-specific photoinitiators are illustrated in FIGS. 4 and 5. FIGS. 4 and 5 are illustrative examples, only, of free radical and acid generation and the choice of photoactive compounds depends on the wavelengths that are used as well as the polymeric material that can be transformed by these species when used, for example, for photoinitiated polymerization. A common characteristic in each of these representative cases of FIGS. 4 and 5 is the multi-photon specificity of the radical and acid forming reactions.

FIG. 4 shows the chemical consequences 400 of two-color excitation of the aromatic di-ketone, benzil. Benzil 402 absorbs light having a wavelength λ₁ 404 in the near ultraviolet (UV) region of the spectrum (for example, emitted by an excimer laser emitting at 308 nm) and following excitation to an excited singlet state S₁ 406 rapidly (picoseconds) and efficiently (quantum yield˜1) intersystem crosses to form the lowest excited triple state T₁ 408. This triplet state 408 has insufficient energy to undergo efficient reaction either intermolecularly (with quenchers) or intramolecularly (for example, bond cleavage) and as a result relaxes with near unity yield to the ground state. However, if this benzil triplet state T₁ 408 is itself excited by the output of a 480 nm dye laser, light with wavelength λ₂ 410, a highly energetic upper triplet state Tₙ 412 is formed that has sufficient energy to undergo intramolecular bond cleavage 414 to yield two benzoyl free radicals 416, which, in the presence of the appropriate polymer can initiate further polymerization.

FIG. 5 shows an example of multi-photon-specific generation 500 of an acid subsequent to excitation with two light sources of different wavelengths. In FIG. 5, phenothiazine 502 is photoexcited by light λ₁ 504 in the UV region (for example, by an excimer laser emitting at 308 nm) yielding the lowest excited singlet state S₁ 506, which undergoes conversion to the lowest triplet state T₁ 508 by intersystem crossing. This triplet state T₁ 508 can be subsequently excited in the visible region by a second light source, having a wavelength λ₂, 510 and to produce an excited triplet state Tₙ 512 which undergoes photoionization, i.e., ejection of an electron, 514 to form a positively charged radical species or cation radical 516. This cation radical 516 subsequently undergoes deprotonation to yield a neutral radical 520 and a proton 522, the latter being the acid species important in the polymerization process.

Several other realizations of the concepts of the present invention are possible. For example, any means which separates two imaging processes can be used in place of the two wavelength approach described hereinbefore in preferred embodiments. Thus two polarizations of light, two optical angular momentum states of light, two pulse widths, without limitation, can be exploited. Similarly, any means of forming an excitation or reaction that depends upon a product of intensities differing according to the two components in the imaging process may be utilized. For example, this includes processes that involve virtual as well as true intermediate states, processes that involve subsequent reactions, whether spontaneous or promoted, processes that depend upon quantum selection rules for wavelength, polarization, angular or linear momentum, and non-quantum effects that involve chemical intermediaries. Also included are processes in which the result of excitation by the two image intensities results in a reversible excitation leading to emission of a photon that may be used to expose another photographic media or which results in the reversible or irreversible formation of a catalyst that promotes another separate exposure or polymerization reactions.

In various aspects, the present invention provides an enhancement to the fundamental resolution limit of greater than a factor of two. Given n imaging processes with n discernable optical modalities (frequencies, polarizations, optical angular momentum states, etc.) and an exposure process that forms a final product in any fashion that depends upon the product of the intensities derived from all n images, an n time improvement in the fundamental limit to the feature size over that of the largest wavelength of light involved in the imaging processes can be obtained.

In view of the wide variety of embodiments to which the principles of the present invention can be applied, it should be understood that the illustrated embodiments are exemplary only, and should not be taken as limiting the scope of the present invention. For example, the steps of the flow diagrams may be taken in sequences other than those described, and more or fewer elements may be used in the block diagrams. While various elements of the preferred embodiments have been described as being implemented in software, other embodiments in hardware or firmware implementations may alternatively be used, and vice-versa.

It will be apparent to those of ordinary skill in the art that methods involved in the system and method for sub-wavelength imaging and forming a photolithographic pattern can be embodied in a computer program product that includes a computer usable medium. For example, such a computer usable medium can include a readable memory device, such as, a hard drive device, a CD-ROM, a DVD-ROM, or a computer diskette, having computer readable program code segments stored thereon. The computer readable medium can also include a communications or transmission medium, such as, a bus or a communications link, either optical, wired, or wireless having program code segments carried thereon as digital or analog data signals.

The claims should not be read as limited to the described order or elements unless stated to that effect. Therefore, all embodiments that come within the scope and spirit of the following claims and equivalents thereto are claimed as the invention.

1. A method of forming a photolithographic pattern comprising the steps of:
providing a surface having a multi-photon-specific photoinitiator material disposed thereon;
irradiating in a first irradiation pattern at least a portion of the multi-photon-specific photoinitiator material with a first wavelength of light capable of electronically exciting the irradiated portion of the multi-photon-specific photoinitiator to a first excited electronic state;
irradiating in a second irradiation pattern at least a portion of the multi-photon-specific photoinitiator material with a second wavelength of light, the second wavelength of light being capable of electronically exciting the portion of the multi-photon-specific photoinitiator irradiated by both the first wavelength of light and the second wavelength of light to a second excited electronic state, the multi-photon-specific photoinitiator material in the second excited electronic state being capable of undergoing a chemical reaction to form a photolithographic pattern on the surface.

2. The method of claim 1, wherein the surface comprises one or more layers of material on a semiconductor substrate.

3. The method of claim 1, wherein the multi-photon-specific photoinitiator material comprises benzil.

4. The method of claim 1, wherein the multi-photon-specific photoinitiator material comprises phenothiazine.

5. The method of claim 1, wherein the first wavelength of light comprises light having a wavelength in the range between about 100 nanometers and 1100 nanometers.

6. The method of claim 1, wherein the second wavelength of light comprises light having a wavelength in the range between about 100 nanometers and 1100 nanometers.

7. The method of claim 1, wherein the first excited electronic state comprises a singlet state.

8. The method of claim 1, wherein the second excited electronic state comprises a triplet state.

9. The method of claim 1, wherein:
the step of irradiating in a first irradiation pattern further comprises imaging the first wavelength of light onto the multi-photon-specific photoinitiator material through a first photolithographic mask; and
the step of irradiating in a second irradiation pattern further comprises imaging the second wavelength of light onto the multi-photon-specific photoinitiator material through a second photolithographic mask different from the first photolithographic mask.

10. The method of claim 1, wherein the chemical reaction comprises acid generation.

11. The method of claim 1, wherein the chemical reaction comprises free radical generation.

12. The method of claim 1, wherein the chemical reaction comprises polymerization.

13. The method of claim 1, wherein the chemical reaction comprises generating a material resistant to acid when contacted with a developing solution.

14. The method of claim 1, wherein the photolithographic pattern on the surface comprises an etching mask for the surface.

15. The method of claim 1, wherein the photolithographic pattern comprises at least one feature having a dimension smaller than λ/(2 NA), where λ is the first wavelength of light or the second wavelength of light, whichever wavelength is shorter, and NA is the numerical aperture of an imaging system used to irradiate the multi-photon-specific photoinitiator with the light of wavelength λ.

16. The method of claim 1, further comprising the step of:
irradiating in a third irradiation pattern at least a portion of the multi-photon-specific photoinitiator material with a third wavelength of light, different from the first wavelength of light and the second wavelength of light, the third wavelength of light capable of electronically exciting the portion of the multi-photon-specific photoinitiator to be irradiated by both the first wavelength of light and the third wavelength of light to a third excited electronic state having an energy greater than the first excited electronic state but less than the second excited electronic state, wherein the second wavelength of light is capable of electronically exciting the portion of the multi-photon-specific photoinitiator irradiated by the first wavelength of light, the third wavelength of light and the second wavelength of light to a second excited electronic state.

17. A method of semiconductor fabrication capable of permitting the formation of an imaged feature having a dimension smaller than λ/(2 NA), where λ is the smallest wavelength of imaging light, and NA is the numerical aperture of the imaging system, comprising the steps of:
providing a surface having a multi-photon-specific photoinitiator material disposed thereon;
imaging in a pattern each of two or more different wavelengths of light onto the multi-photon-specific photoinitiator material to form a photolithographic pattern on the surface where each of the patterns of the two or more different wavelengths of light overlap.

18. The method of claim 17, wherein the photolithographic pattern comprises at least one feature having a dimension smaller than λ/(2 NA), where λ is the shortest of the two or more wavelengths of light, n is the number of different wavelengths of light imaged in a pattern onto the multi-photon-specific photoinitiator material, and NA is the numerical aperture of an imaging system used to irradiate the multi-photon-specific photoinitiator with the light of wavelength λ.

19. The method of claim 17, wherein the surface comprises one or more layers of material on a semiconductor substrate.

20. The method of claim 17, wherein the step of imaging further comprises:
irradiating in a first irradiation pattern at least a portion of the multi-photon-specific photoinitiator material with a first wavelength of light capable of electronically exciting the irradiated portion of the multi-photon-specific photoinitiator to a first excited electronic state; and
irradiating in a second irradiation pattern at least a portion of the multi-photon-specific photoinitiator material with a second wavelength of light, different from the first wavelength of light, the second wavelength of light capable of electronically exciting the portion of the multi-photon-specific photoinitiator irradiated by both the first wavelength of light and the second wavelength of light to a second excited electronic state, the multi-photon-specific photoinitiator material in the second excited electronic state capable of undergoing a chemical reaction to form a photolithographic pattern on the surface.

21. The method of claim 20, wherein the chemical reaction comprises acid generation.

22. The method of claim 20, wherein the chemical reaction comprises free radical generation.

23. The method of claim 20, wherein the chemical reaction comprises polymerization.

24. The method of claim 20, wherein the chemical reaction comprises generating a material resistant to acid when contacted with a developing solution.

25. The method of claim 17, wherein the multi-photon-specific photoinitiator material comprises benzil.

26. The method of claim 17, wherein the multi-photon-specific photoinitiator material comprises phenothiazine.

27. The method of claim 17, wherein the photolithographic pattern on the surface comprises an etching mask for the surface.

28. A method of forming a photolithographic pattern comprising the steps of:
providing a surface having a multi-photon-specific photoinitiator material disposed thereon; irradiating in a first irradiation pattern at least a portion of the multi-photon-specific photoinitiator material with a first modality of light;
irradiating in a second irradiation pattern at least a portion of the multi-photon-specific photoinitiator material with a second modality of light, different from the first modality of light, the second modality of light capable initiating a chemical reaction in the portion of the multi-photon-specific photoinitiator irradiated by both the first modality of light and the second modality of light to form a photolithographic pattern on the surface.

29. The method of claim 28, wherein a modality of light comprises one or more of wavelength, polarization, optical angular momentum state, and coherent light pulse width.

30. The method of claim 28, wherein the surface comprises one or more layers of material on a semiconductor substrate.

31. The method of claim 28, wherein the multi-photon-specific photoinitiator material comprises benzil.

32. The method of claim 28, wherein the multi-photon-specific photoinitiator material comprises phenothiazine.

33. The method of claim 28, wherein the photolithographic pattern on the surface comprises an etching mask for the surface.
